(19) United States
(12) Patent Application Publication
(10) Pub. No.: US 2017/0358535 A1
(43) Pub. Date: Dec. 14, 2017

(54) SEMICONDUCTOR PACKAGES

(71) Applicants: Hyein YOO, Pyeongtaek-si (KR); Won-Gi CHANG, Hwaseong-si (KR)

(72) Inventors: Hyein YOO, Pyeongtaek-si (KR); Won-Gi CHANG, Hwaseong-si (KR)

(21) Appl. No.: 15/617,943

(22) Filed: Jun. 8, 2017

(30) Foreign Application Priority Data
Jun. 13, 2016 (KR) 10-2016-0073288

(51) Int. Cl. H01L 23/538; H01L 23/31; H01L 21/56; H01L 25/10; H01L 25/00; H01L 21/48

(52) U.S. Cl. CPC H01L 23/5389; H01L 23/5384; H01L 25/50; H01L 21/4853; H01L 23/5386; H01L 21/486; H01L 21/563; H01L 23/5383; H01L 25/105; H01L 23/3114; H01L 21/4857; H01L 2225/1035; H01L 2225/1058

(57) ABSTRACT

Provided are a semiconductor package. The semiconductor package comprises a redistribution substrate, an interconnect substrate on the redistribution substrate and including a hole penetrating therethrough and a recess region in a lower portion thereof, a semiconductor chip on the redistribution substrate and disposed in the hole of the interconnect substrate, and a molding layer covering the semiconductor chip and the interconnect substrate. The recess region is connected to the hole. The mold layer fills the recess region and a gap between the semiconductor chip and the interconnect substrate.

### CROSS-REFERENCE TO RELATED APPLICATIONS

This U.S. nonprovisional patent application claims priority under 35 U.S.C. §119 of Korean Patent Application 10-2016-0073288 filed on Jun. 13, 2016, the entire contents of which are hereby incorporated by reference.

### BACKGROUND

The present disclosure relates to a semiconductor package and a method for manufacturing the same and, more particularly, to a semiconductor package including a redistribution substrate and a method for manufacturing the same.

A semiconductor package is provided to implement an integrated circuit chip to be suitable for use in an electronic appliance. Typically, in a semiconductor package, a semiconductor chip is mounted on a printed circuit board (PCB) and bonding wires or bumps are used to electrically connect the semiconductor chip to the printed circuit board. With the recent developments in the electronic industry, semiconductor packages are variously developed to reach the goals of compact size, light weight, and/or low manufacturing cost.

A size of semiconductor chip becomes smaller with high integration of the semiconductor chip. It however is difficult to adhere, handle, and test solder balls due to the small size of the semiconductor chip. Additionally, there are problems of acquiring diversified mount boards in accordance with the size of the semiconductor chip.

A fan-out panel level package is proposed to address some of these issues.

### SUMMARY

Embodiments of the present inventive concept provide a semiconductor package and a method for manufacturing the same capable of minimizing faults occurred between a carrier substrate and a semiconductor chip during the fabrication process.

According to exemplary embodiments, a semiconductor package may comprise: a redistribution substrate; an interconnect substrate on the redistribution substrate, the interconnect substrate including a hole penetrating therethrough and a recess region in a lower portion thereof; a semiconductor chip on the redistribution substrate, the semiconductor chip being disposed in the hole of the interconnect substrate; and a molding layer covering the semiconductor chip and the interconnect substrate. The recess region may be connected to the hole. The mold layer may fill the recess region and a gap between the semiconductor chip and the interconnect substrate.

According to exemplary embodiments, a method for manufacturing a semiconductor package may comprise: forming a hole that penetrates inside of an interconnect substrate; etching the interconnect substrate to form, on a bottom surface of the interconnect substrate, a recess region connected to the hole; providing a carrier substrate on the bottom surface of the interconnect substrate; providing a semiconductor chip in the hole; forming a mold layer by coating a molding member on the semiconductor chip and the interconnect substrate; removing the carrier substrate to expose a bottom surface of the semiconductor chip and the bottom surface of the interconnect substrate; and forming a redistribution substrate on the bottom surface of the semiconductor chip and the bottom surface of the interconnect substrate.

According to exemplary embodiments, a semiconductor package includes a first substrate including a base layer including an insulative material; a hole in the first substrate, the hole defined by inner sidewalls of the first substrate; a first semiconductor chip disposed in the hole; and a second substrate on which the first substrate and the first semiconductor chip are directly mounted. The inner sidewalls of the first substrate include a recess at a bottom of the hole.

According to exemplary embodiments, a semiconductor package includes an upper substrate including a base layer including an insulative material; a hole in the upper substrate, the hole defined by inner sidewalls of the upper substrate; a first semiconductor chip disposed in the hole; and a lower substrate on which the upper substrate and the first semiconductor chip are directly mounted. A portion of the upper substrate horizontally protrudes beyond a portion of the upper substrate that contacts the lower substrate.

### BRIEF DESCRIPTION OF THE DRAWINGS

FIGS. 1A and 1B are plan views for explaining a semiconductor package according to exemplary embodiments of the present inventive concept.

FIGS. 2A to 2C are cross-sectional views for explaining a semiconductor package according to exemplary embodiments of the present inventive concept.

FIG. 3 is a plan view for explaining a method for manufacturing a semiconductor package according to exemplary embodiments of the present inventive concept.

FIGS. 4A to 4I are cross-sectional views for explaining a method for manufacturing a semiconductor package according to exemplary embodiments of the present inventive concept.

FIG. 4J is a cross-sectional view for explaining a semiconductor package according to exemplary embodiments of the present inventive concept.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, and may be referred to using language such as “in one embodiment,” these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present. Other words used to describe the relationship between elements should be interpreted in a like fashion (e.g., “between” versus “directly between,” “adjacent” versus “directly adjacent,” etc.).

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein should be interpreted accordingly. It will be discussed in detail about a semiconductor package according to the present inventive concept accompanying drawings.

A carrier tape may be used to form certain types of packages. For example, in one embodiment, a substrate such as a printed circuit board (PCB) and a semiconductor chip formed in a hole of the substrate may be placed on a carrier tape. Subsequently, an insulating layer, such as a mold layer, may be formed on the top surfaces of the semiconductor chip and substrate. The mold layer may also fill in spaces between inner sidewalls (e.g., side surfaces) of the substrate that form the hole, and outer sidewalls (e.g., side surfaces) of the semiconductor chip. For example, there may be a space between the sidewalls of the semiconductor chip and the sidewalls of the hole. As such, part of the mold layer may extend to a surface of the carrier tape where it meets the outer sidewalls of the semiconductor chip and inner sidewalls of the substrate, to fill in the space. In some situations, for example due to the use of an adhesive for the carrier tape that has a reduced adhesive force to allow for easier removal, some of the material that forms the mold layer, such as a resin, can bleed to flow into the interface between the carrier tape and the semiconductor chip. This resin may remain on the semiconductor chip after removal of the carrier tape, which can cause defects. Therefore, various embodiments herein may reduce such defects, and have other beneficial effects.

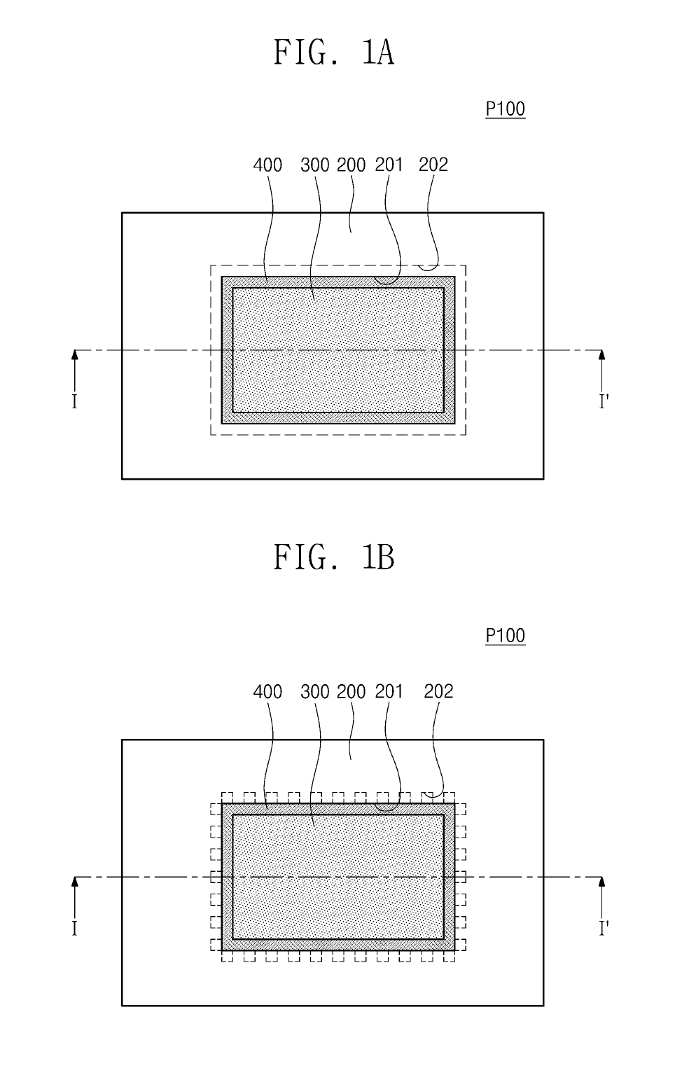

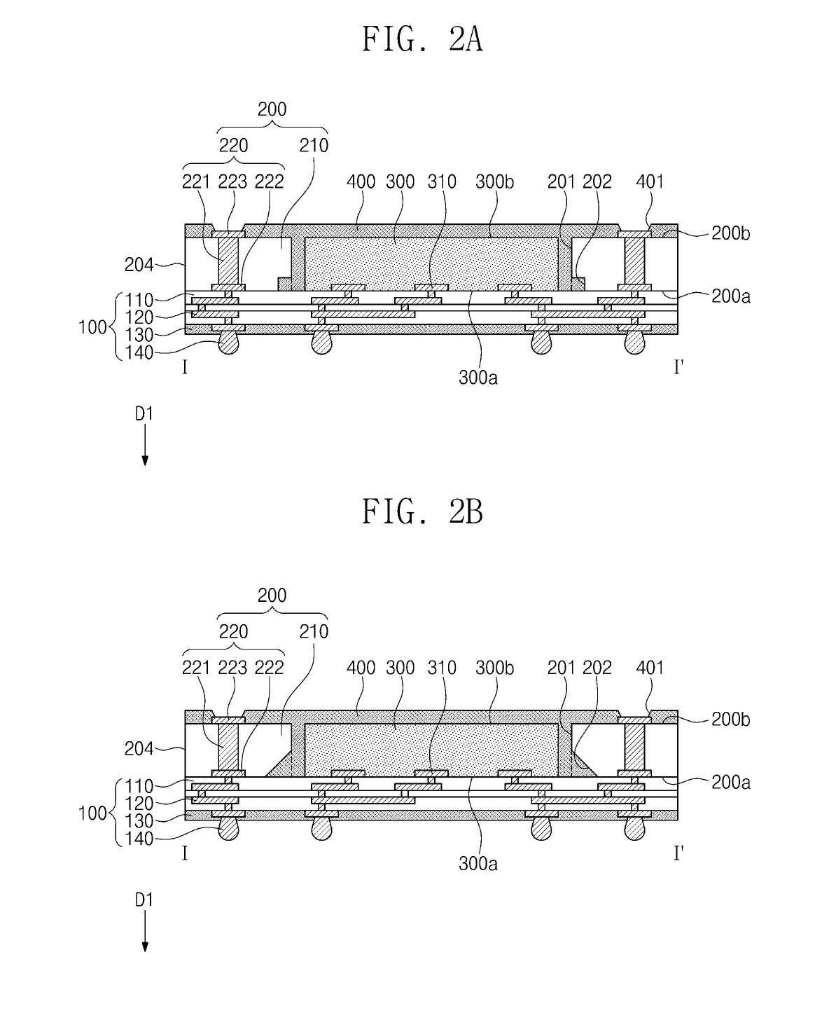

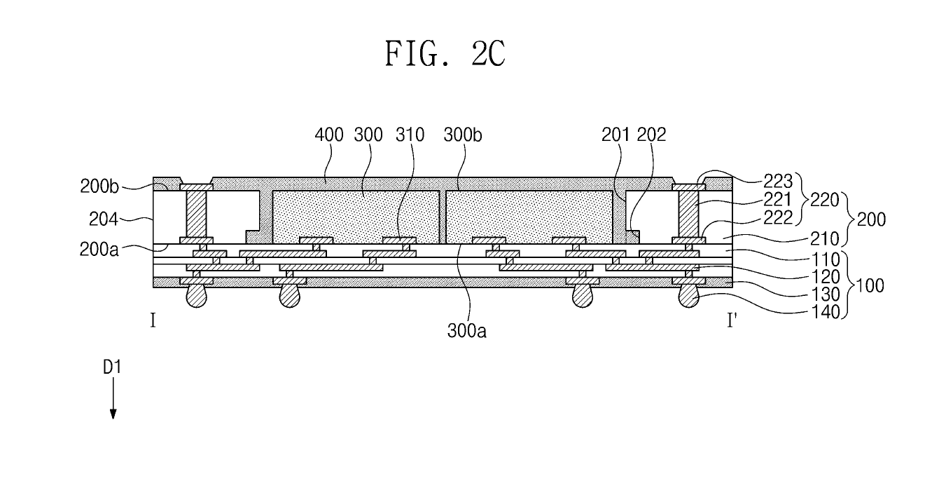

FIGS. 1A and 1B are plan views for explaining a semiconductor package according to exemplary embodiments of the present inventive concept. FIGS. 2A to 2C are cross-sectional views for explaining a semiconductor package according to exemplary embodiments of the present inventive concept. FIGS. 2A to 2C correspond to cross-sectional views taken along line I-I′ of FIG. 1A or 1B. For convenience of the description, FIGS. 1A and 1B omit illustrating upper pads 223, through vias 221, lower pads 222, and a portion of first molding layer 400.

Referring to FIGS. 1A and 2A, a first substrate 100 may be provided. The first substrate 100 may be a redistribution substrate. In one embodiment, the first substrate 100 may include insulative patterns 110 and conductive patterns 120. The conductive patterns 120 may include one or more conductive layers between the insulative patterns 110 and one or more vias penetrating the insulative patterns 110. The conductive patterns 120 may be surrounded by the insulative patterns 110. The conductive patterns 120 may redistribute signals passing between outside of the package (e.g., via external connection terminals 140) and a first semiconductor chip 300 mounted on the first substrate 100. For example, a first package P100 may have a fan-out structure by means of the first substrate 100. The conductive patterns 120 may include metal or other conductive material. A protection layer 130 may be disposed on a bottom surface of the first substrate 100. The protection layer 130 may include, for example, an ABF (Ajinomoto Build-up Film) or an insulative polymer such as an epoxy-based polymer. External terminals 140, also referred to as external connection terminals 140, or external package terminals 140, may be disposed on the bottom surface of the first substrate 100. The external terminals 140 may be electrically connected to the conductive patterns 120.

It should be noted that certain of the conductive patterns 120 connect between the external terminals 140 and the first semiconductor chip 300, for example to connect to an integrated circuit of the first semiconductor chip 300. These conductive patterns, also referred to as redistribution lines, may be described herein as first conductive patterns, or first redistribution lines. Certain other of the conductive patterns 120 may connect to conductive paths (e.g., through substrate vias) formed in the interconnect substrate 200, to be described in more detail below. These conductive patterns, also referred to as redistribution lines, may be described herein as second conductive patterns, or second redistribution lines. In some embodiments, the first redistribution lines connect to respective first external package terminals 140, and the second redistribution lines connect to respective second external package terminals 140. The first redistribution lines may be connected to semicondcutor chip 300, and therefore may be for connecting external package terminals with a bottom chip of a bottom package in a package-on-package device. In some embodiments, the second redistribution lines may be connected to a second semiconductor chip stacked on the first semiconductor chip 300 in a package-on-package manner (described in more detail below), and may be for connecting external package terminals with the second semiconductor chip, which may be part of a top package. Certain of the first redistribution lines may be electrically isolated from the second redistribution lines, and vice versa. In some instances, certain of the first redistribution lines may be electrically connected to certain the second redistribution lines.

An interconnect substrate 200 may be disposed on the first substrate 100. The interconnect substrate 200, also referred to herein as an interconnection substrate, may be disposed to electrically interconnect a first semiconductor package to a second device such as a second semiconductor package. In some embodiments, the interconnect substrate 200 may be disposed directly on the first substrate 100 (e.g., so that a bottom surface of the interconnect substrate 200 contacts a top surface of the first substrate 100). The interconnect substrate 200 may include a hole 201 penetrating thereinside (also described as an opening). For example, the hole 201 may have an open hole shape connecting a bottom surface 200a of the interconnect substrate 200 to a top surface 200b of the interconnect substrate 200. The hole 201 may penetrate through the entire thickness (in a vertical direction) of the interconnect substrate 200. As viewed in a plan view, the hole 201 may have a planar shape corresponding to the first semiconductor chip 300 which is discussed in detail later. FIG. 1A illustrates the hole 201 having a rectangular planar shape, but the present inventive concept is not limited thereto.

The interconnect substrate 200 may include a recess region 202 disposed on the bottom surface 200a thereof. For example, the interconnect substrate 200 may include a recess at a bottom of the hole 201. In detail, the recess region 202 may extend from the bottom surface 200a of the interconnect substrate 200 toward the top surface 200b of the interconnect substrate 200. The recess region 202 may be in fluid communication with and may connect to the hole 201. For example, the recess region 202 may have a shape extending from the hole 201 toward an edge side 204 of the interconnect substrate 200. As viewed in a plan view, the recess region 202 may surround the hole 201. For example, the recess region 202 may have a ring shape in contact with an outer side of the hole 201. As can be seen, as a result of the recess, at least part of the bottom surface of the interconnect substrate 200 vertically overlaps but does not contact a top surface of the redistribution substrate 100 on which the interconnect substrate 200 is directly mounted. It should be noted that in different parts of this specification and claims, the redistribution substrate 100 may be referred to as a first substrate or a second substrate, and the interconnect substrate 200 may be referred to as a second substrate or a first substrate. Thus, the terms “first” and “second” are used in the manner as mere labels for the different substrates, unless the context indicates otherwise.

In certain embodiments, the recess region 202 may be provided in plural. As shown in FIG. 1B, the recess regions 202 may be arranged along the outer side of the hole 201, for example, at a bottom of the hole 201. In this case, the recess regions 202 may be arranged at a regular interval. FIG. 2A illustrates the recess region 202 having a rectangular sectional shape, but the present inventive concept is not limited thereto. The recess region 202 may have a shape whose depth (or vertical height) decreases with approaching the edge side 204 of the interconnect substrate 200 from the hole 201. For example, as shown in FIG. 2B, the recess region 202 may have a tapered sectional shape whose one side surface is inclined at a constant slope so as to approach the edge side 204 of the interconnect substrate 200. Alternatively, though not shown in the figures, the recess region 202 may have a stepwise sectional shape that is inclined downward from the hole 201 toward the edge side 204 of the interconnect substrate 200.

The interconnect substrate 200 may include a base layer 210 and a conductive member 220 in the base layer 210. For example, a printed circuit board (PCB) may be used as the base layer 210 for the interconnect substrate 200. The base layer 210 may be in contact with the first substrate 100. Thus, the bottom surface 200a of the interconnect substrate 200 may contact a top surface of the first substrate 100. The conductive member 220 may be disposed in an edge portion of the interconnect substrate 200, and the hole 201 may be disposed in a center portion of the interconnect substrate 200. The conductive member 220 may include lower pads 222, through vias 221, and upper pads 223. The lower pads 222 may be disposed on a lower portion of the interconnect substrate 200. The through vias 221 may penetrate the base layer 210. The upper pads 223 may be provided on an upper portion of the interconnect substrate 200 and connected to at least one of the through vias 221. The number of the upper pads 223 may be different from the number of the external terminals 140. The upper pads 223 may be electrically connected to the lower pads 222 through the through vias 221. The lower pads 222 may be coupled to and electrically connected to the conductive patterns 120.

In some embodiments, the interconnect substrate 200 may be a single-layer substrate. The interconnect substrate 200 may include an insulating material through which conductive paths (e.g., through substrate vias) are formed for connecting between the redistribution substrate 100 (e.g., redistribution lines in the redistribution substrate that connect to external package connection terminals) and an upper semiconductor chip or package. As a result of the recess in the interconnect substrate 200 (e.g., a recess in the base layer 210), a top portion of the base layer 210 that forms the second substrate forms an overhang of the base layer 210 over the first substrate. Also, as can be seen, a portion of the second substrate horizontally protrudes beyond a portion of the second substrate that contacts the first substrate. The base layer 210 may be continually formed from a surface where it contacts the redistribution substrate 100 to a surface where it contacts a molding layer 400. The base layer 210 may also be continually formed from a center portion to an edge portion, and continuing to a side surface above the recess region 202.

A first semiconductor chip 300 may be disposed on the first substrate 100. The first semiconductor chip 300 may be disposed in the hole 201 of the interconnect substrate 200. As viewed in a plan view, the first semiconductor chip 300 may have a shape smaller than that of the hole 201. For example, a gap may be present between the first semiconductor chip 300 and an inner wall of the hole 201. The first semiconductor chip 300 may have a bottom surface 300a facing the first substrate 100 and a top surface 300b opposite the bottom surface 300a. The bottom surface 300a of the first semiconductor chip 300 may be in contact with the top surface of the first substrate 100. For example, the bottom surface 300a of the first semiconductor chip 300 may be positioned at the same level as the bottom surface 200a of the interconnect substrate 200. The first semiconductor chip 300 may include first chip pads 310 disposed in a lower portion thereof. The first chip pads 310 may be electrically connected to the conductive patterns 120 of the first substrate 100 and may connect to an integrated circuit of the first semiconductor chip 300. The first semiconductor chip 300 may be, for example, a memory chip or an application processor (AP) chip. In other embodiment, a plurality of first semiconductor chips 300 may be disposed in the hole 201. As shown in FIG. 2C, the plurality of first semiconductor chips 300 may be disposed side by side on the first substrate 100. In this case, the plurality of first semiconductor chips 300 may be spaced apart from each other. In other cases, a plurality of first semiconductor chips 300 may be stacked to form a chip stack.

A first molding layer 400 may be provided on the first substrate 100. In detail, the first molding layer 400 may cover the top surface 200b of the interconnect substrate 200 and the top surface 300b of the first semiconductor chip 300. The first molding layer 400 may fill the recess region 202 of the interconnect substrate 200 and a gap between the interconnect substrate 200 and the first semiconductor chip 300. The first molding layer 400 may have a lowermost surface in contact with the top surface of the first substrate 100. The lowermost surface of the first molding layer 400 may be positioned at the same level as the bottom surface 200a of the interconnect substrate 200. The first molding layer 400 may include an ABF (Ajinomoto Build-up Film). Alternatively, the first molding layer 400 may include an insulative polymer such as an epoxy-based polymer or a high molecular substance such as a thermosetting resin. An opening 401 may be formed in the first molding layer 400 so that the upper pads 223 may be exposed through the opening 401. Alternatively, the opening 401 may not be formed.

As described above, a package may include a second substrate, such as an interconnect substrate 200, including a base layer 210 including an insulative material. The second substrate may include a hole 201 defined by inner sidewalls of the interconnect substrate 200. A first semiconductor chip 300 may be disposed in the hole 201. The second substrate 200 and the first semiconductor chip 300 may be directly mounted on a first substrate 100, such as a redistribution substrate 100. In comparison, the first substrate 100 may be referred to as a lower substrate, and the second substrate 200 may be referred to as an upper substrate. The inner sidewalls of the second substrate 200 may include a recess at a bottom of the hole. The first semiconductor chip 300 disposed in the hole 201 includes a top surface, a bottom surface, and outer sidewalls connecting the top surface and the bottom surface. A space may be formed between the outer sidewalls of the first semiconductor chip 300 and the inner sidewalls of the second substrate 200. For example, the space may include the recess and an additional length of horizontal space, for example, at the vertical level where the recess is formed. For example, the additional length of horizontal space may be an amount of space that separates upper portions of the first semiconductor chip 300 from upper portions of the hole 201 in the second substrate 200. The space may be filled with a molding material, such as a first molding layer 400. As can be seen, the space may include a portion horizontally between the outer sidewalls of the first semiconductor chip 300 and the inner sidewalls of the upper substrate, and may also include a portion vertically between the upper substrate and the lower substrate. In some embodiments, as a result of the recess, an upper portion of the inner sidewalls of the upper substrate 200 overhangs the lower substrate 100.

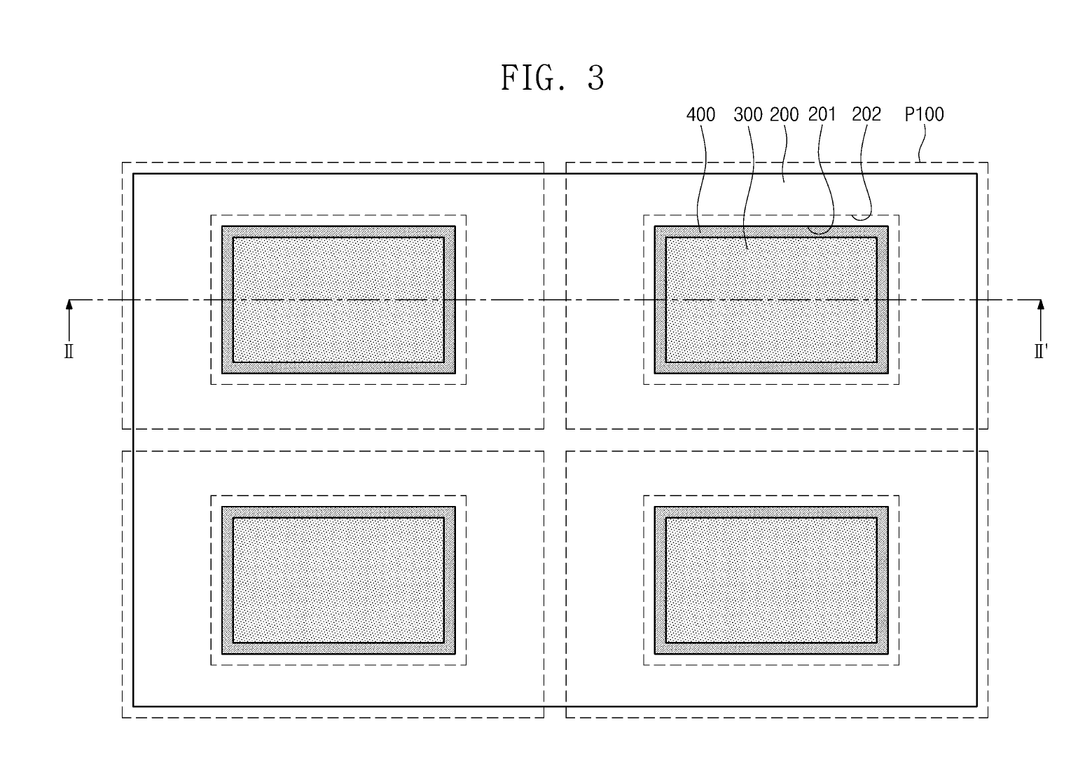

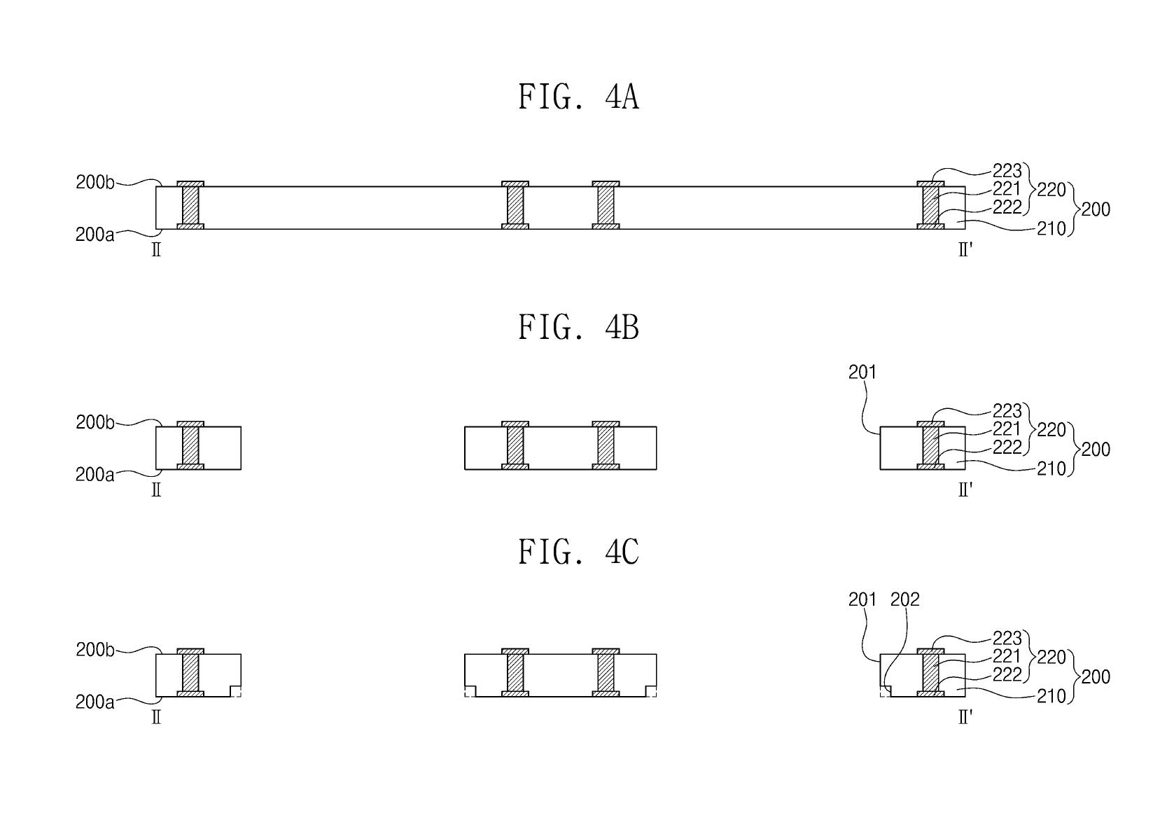

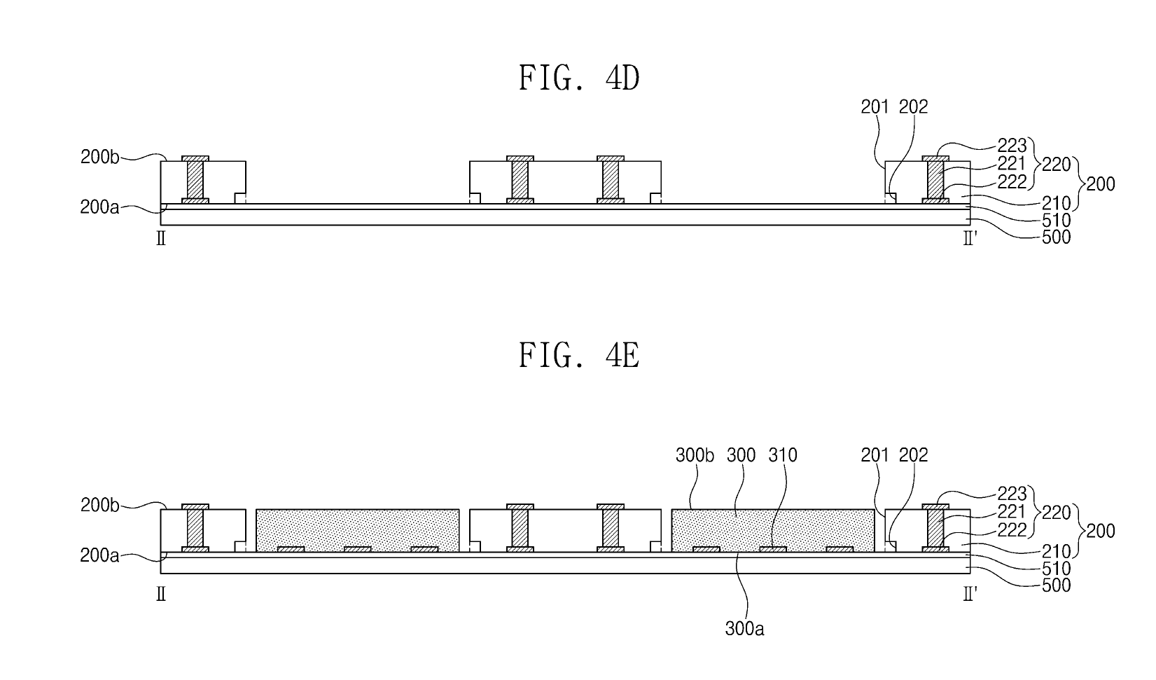

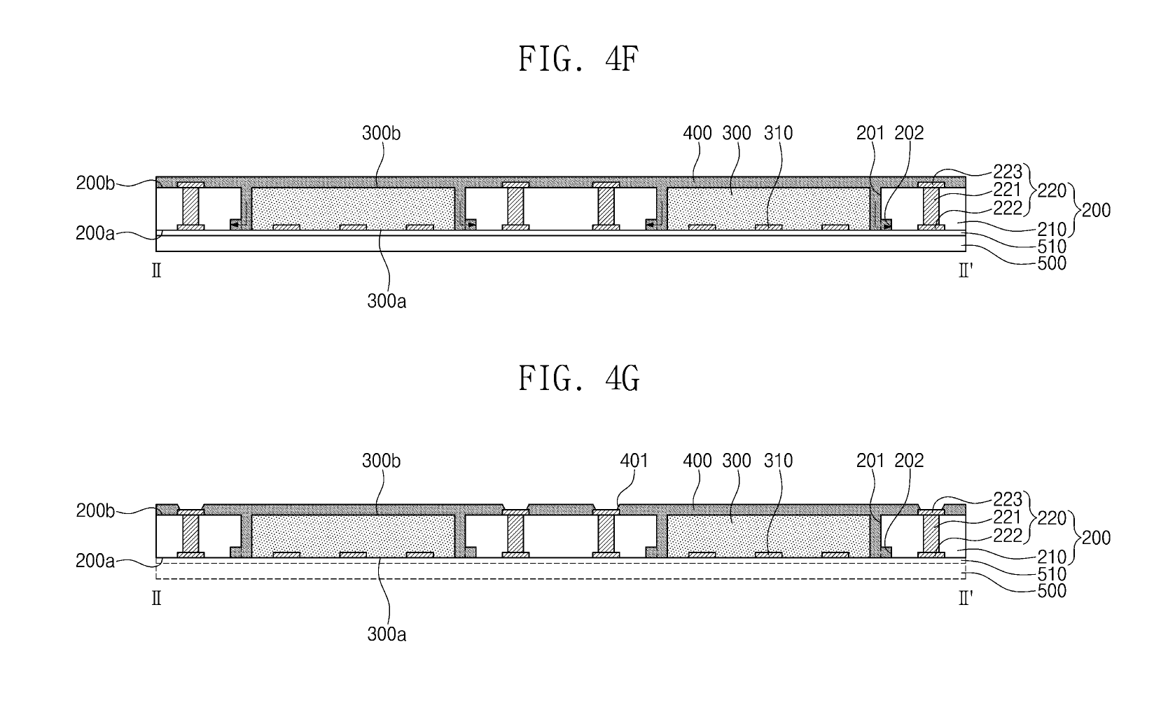

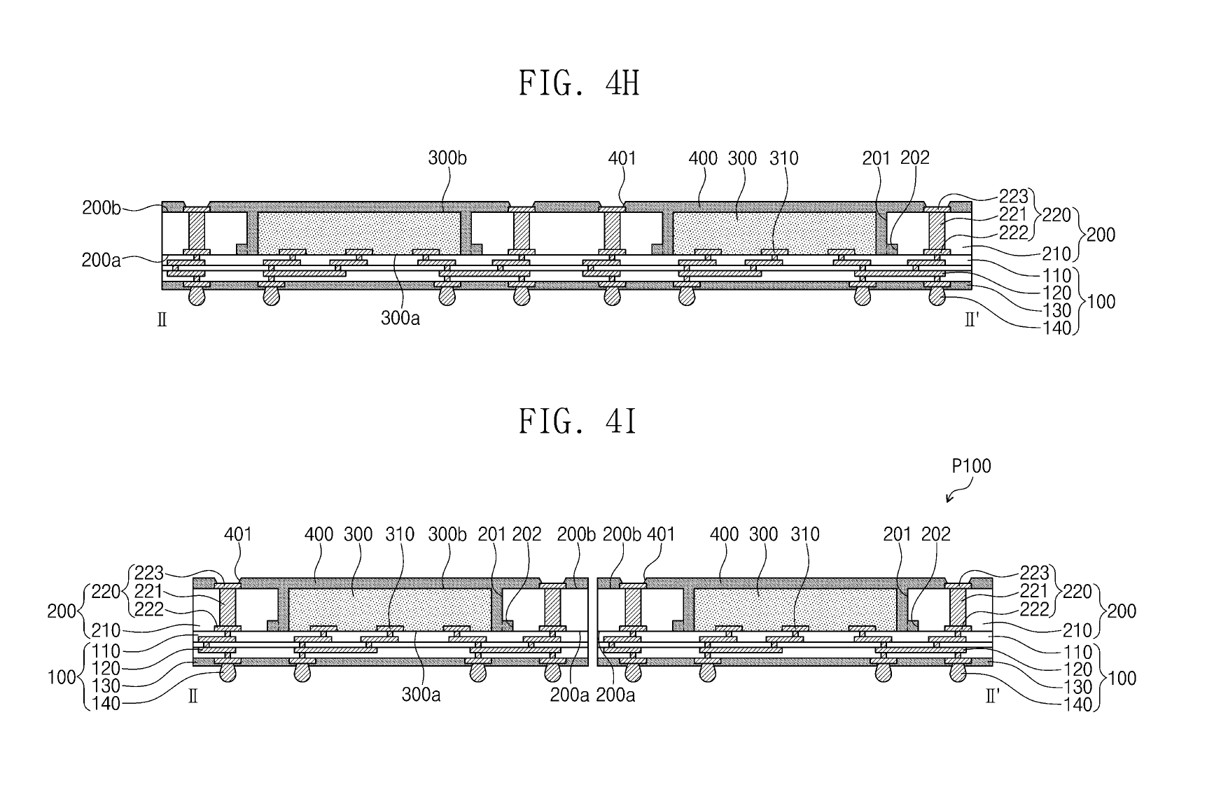

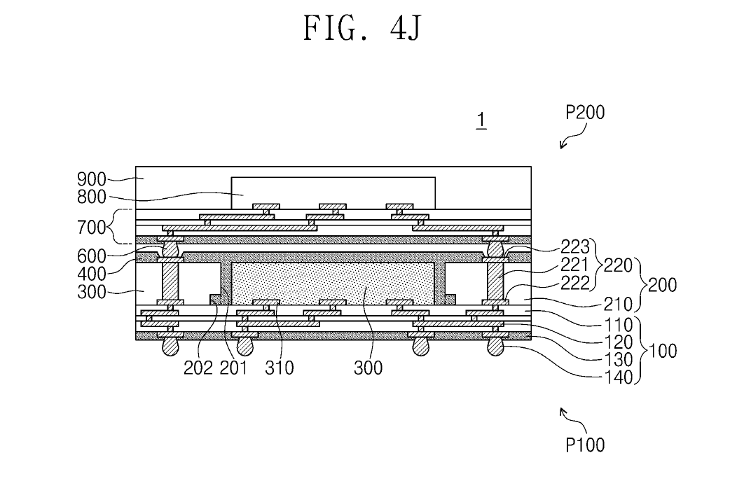

FIG. 3 is a plan view for explaining a method for manufacturing a semiconductor package according to exemplary embodiments of the present inventive concept. FIGS. 4A to 4I are cross-sectional views for explaining a method for manufacturing a semiconductor package according to exemplary embodiments of the present inventive concept. FIGS. 4A to 4I correspond to cross-sectional views taken along line II-II′ of FIG. 3. For convenience of the description, FIG. 3 omits illustrating the upper pads 223, the through vias 221, the lower pads 222, and a portion of the first molding layer 400. Descriptions duplicate with the aforementioned will be hereinafter omitted for brevity of the explanation.

Referring to FIGS. 3 and 4A, an interconnect substrate 200 may be provided. The interconnect substrate 200 may include base layer 210 and a conductive member 220 in the base layer 210. For example, a printed circuit board (PCB) may be used as the interconnect substrate 200. The conductive member 220 may include lower pads 222 disposed in a lower portion of the interconnect substrate 200, upper pads 223 disposed on an upper portion of the interconnect substrate 200, and vias 221 that penetrate the base layer 210 and are electrically connected to the lower and upper pads 222 and 223. For example, the vias 221, the lower pads 222, and the upper pads 223 may be formed by etching the base layer 210 and then filling the etched portion with a conductive material.

Referring to FIGS. 3 and 4B, a hole 201 may be formed in the interconnect substrate 200. The interconnect substrate 200 may be partially removed to form the hole 201 penetrating therethrough. For example, the hole 201 may be formed by performing an etch process such as a laser drilling process, a laser ablation process, or a laser cutting process to form an opening in the interconnect substrate 200. The removed portion of the interconnect substrate 200 may be a zone in which a first semiconductor chip 300 is provided in a subsequent process. The hole 201 may have an open hole shape connecting a bottom surface 200a the interconnect substrate 200 to a top surface 200b of the interconnect substrate 200.

Referring to FIGS. 3 and 4C, a recess region 202 may be formed in the interconnect substrate 200. The bottom surface 200a of the interconnect substrate 200 may be etched to form the recess region 202. For example, the recess region 202 may be formed by performing an etch process such as a laser drilling process, a laser ablation process, or a laser cutting process. In certain embodiments, the formation of the recess region 202 may be carried out simultaneously with the formation of the hole 201. Although FIG. 4C shows the recess region 202 having a shape as shown in FIG. 2A, the recess region 202 may be formed to have a shape as depicted in FIG. 2B.

Referring to FIGS. 3 and 4D, the interconnect substrate 200 may be provided on a carrier substrate 500. The interconnect substrate 200 may be adhered onto the carrier substrate 500. For example, as shown in figures, the carrier substrate 500 may further include an adhesive member 510 provided on a top surface thereof. Alternatively, the carrier substrate 500 may be an adhesive tape.

Referring to FIGS. 3 and 4E, a first semiconductor chip 300 may be provided on the carrier substrate 500. The first semiconductor chip 300 may be provided in the hole 201 of the interconnect substrate 200. In this step, the first semiconductor chip 300 may be adhered onto the carrier substrate 500. The first semiconductor chip 300 may include first chip pads 310 disposed in a lower portion thereof.

Referring to FIGS. 3 and 4F, a first molding layer 400 may be formed on the carrier substrate 500. In detail, a molding member may be coated on the interconnect substrate 200 and the first semiconductor chip 300 and then the molding member may be cured to form the first molding layer 400. In this step, the molding member may fill a gap between the interconnect substrate 200 and the first semiconductor chip 300. For example, as designated by arrows in figures, the molding member coated on the interconnect substrate 200 and the first semiconductor chip 300 may flow into the recess region 202 after passing through the gap between the first semiconductor chip 300 and the interconnect substrate 200. A flow direction of the molding member may run toward the carrier substrate 500 in the gap between the first semiconductor chip 300 and the interconnect substrate 200 and run toward the edge side 204 of the interconnect substrate 200 in the recess region 202. The molding member may include, for example, an ABF (Ajinomoto Build-up Film). Alternatively, the molding member may include an insulative polymer such as an epoxy-based polymer or a high molecular substance such as a thermosetting resin.

In the case that the recess region 202 is not provided, the flow direction of the molding member may run toward the carrier substrate 500 such that the molding member may pressurize the carrier substrate 500 at an end of the gap between the interconnect substrate 200 and the first semiconductor chip 300. This may induce creation of a space between the interconnect substrate 200 and the carrier substrate 500 and/or between the first semiconductor chip 300 and the carrier substrate 500, thereby producing a resin bleeding in which the molding member flows into the space. The molding member flowed into the space may remain as a residue on a bottom surface 300a of the first semiconductor chip 300 and may cause a contact failure between the first semiconductor chip 300 and a first substrate 100 of FIG. 4H in a subsequent process. In a case where the carrier substrate 500 having strong adhesive force is used to resist the pressure applied thereto, an adhesive material may not be entirely removed but may remain as a residue on the bottom surface 300a of the first semiconductor chip 300 in a subsequent process for removing the carrier substrate 500.

In manufacturing a semiconductor package according to some embodiments of the inventive concept, the recess region 202 may be formed to be connected to an end of the gap between the interconnect substrate 200 and the first semiconductor chip such that it may be possible to induce the molding member to flow toward outside the interconnect substrate 200. It may thus be achievable to disperse the pressure applied to the carrier substrate 500 and prevent the molding member from flowing into an interface between the first semiconductor chip 300 and the carrier substrate 500. In addition, the flow direction of the molding member may be abruptly changed when the molding member flows into the recess region 202 and thus the flow of the molding member may create turbulence in the recess region 202. The molding member may therefore fill up the recess region 202 and the gap between the interconnect substrate 200 and the first semiconductor chip 300, and the occurrence of a void may be reduced or suppressed. Thereafter, an opening 401 may be formed in the first molding layer 400. For example, the opening 401 may expose the upper pads 223 of the interconnect substrate 200. Alternatively, the opening 401 may not be formed. In some embodiments, the size of the recess is selected to allow for sufficient flow of the molding member to avoid bleeding under the semiconductor chip 300. For example, a horizontal length of the recess (as shown in the cross-section of the various figures) can be a certain percentage of the height of the interconnect substrate 200 in a vertical direction between topmost and bottommost surfaces, such as 20% or more (e.g., in some cases it can be between 20% and 75%, or as much as 100%). In addition, in some embodiments, the width of the recess region 202 combined with the width of the the hole 201 is smaller than half of the length between an outer sidewall of the interconnect substrate 200 and a hole in the conductive member 220 closest to the outer sidewall of the interconnect substrate 200. In some embodiments, the height of the recess between a top surface of the first substrate 100 and a bottom surface of the interconnect substrate 200 is smaller than half of the height of the interconnect substrate wherein the recess region 202 is not located. In some embodiments, a width of the recess region 202 up to but not including the hole 201 may be smaller than a width of the hole 201, but may be greater than 30% of the width of the hole 201.

Referring to FIGS. 3 and 4G, the carrier substrate 500 may be removed. As designated by a dotted line shown in figures, the removal of the carrier substrate 500 may expose the bottom surface 300a of the first semiconductor chip 300 and the bottom surface 200a of the interconnect substrate 200. In this step, the adhesive member 510 may also be removed together with the carrier substrate 500.

Referring to FIGS. 3 and 4H, a first substrate 100 may be formed on the bottom surface 300a of the first semiconductor chip 300 and the bottom surface 200a of the interconnect substrate 200. For example, insulative patterns 110 and conductive patterns 120 may be formed on the bottom surface 300a of the first semiconductor chip 300 and the bottom surface 200a of the interconnect substrate 200, thereby fabricating the first substrate 100. The first substrate 100 may be a redistribution substrate, for example, for redistributing signals from external package connection terminals to an internal chip of the package. For example, an insulative layer may be formed on the bottom surface 300a of the first semiconductor chip 300 and the bottom surface 200a of the interconnect substrate 200 and then the insulative layer may be patterned to form the insulative pattern 110. In this step, the first chip pads 310 of the first semiconductor chip 300 and the lower pads 222 of the interconnect substrate 200 may be exposed through the insulative pattern 110. A conductive layer may be formed on a bottom surface of the insulative pattern 110 and then the conductive layer may be patterned to form the conductive patterns 120. In this step, the conductive patterns 120 may be electrically connected to the first chip pads 310 of the first semiconductor chip 300 and the lower pads 222 of the interconnect substrate 200. An insulative layer may be formed on bottom surfaces of the conductive patterns 120 and then the insulative layer may be patterned to form other insulative pattern 110. In this step, the conductive patterns 120 may be partially exposed through the other insulative pattern 110. A protection layer 130 may be formed on the bottom surfaces of the conductive patterns 120. For example, the protection layer 130 may include the same material as the first molding layer 400. However, the material of the protection layer 130 may not be limited thereto.

External terminals 140 may be formed on a bottom surface of the first substrate 100 and connected to the conductive patterns 120. For example, the protection layer 130 may be patterned to expose portions of the conductive patterns 120. The external terminals 140 may be formed on the exposed portions of the conductive patterns 120. The external terminals 140 may not be aligned with the upper pads 223 in a first direction D1, as shown in FIGS. 2A to 2C (e.g., in particular, the external terminals 140 may not be aligned with the upper pads 223 to which they are electrically connected). The number of the external terminals 140 may be different from the number of the upper pads 223. The external terminals 140 may be electrically connected to the upper pads 223 through the conductive patterns 120, the lower pads 222, and the through vias 221.

Referring to FIGS. 1A, 3 and 4I, the first substrate 100 and the interconnect substrate 200 may be sawed to form first packages P100. Each of the first packages P100 may have a cross-section like that shown in FIG. 2A.

FIG. 4J is a cross-sectional view for explaining a semiconductor package according to exemplary embodiments of the present inventive concept. FIG. 4J corresponds to a cross-sectional view taken along line II-II′ of FIG. 3, according to some embodiments. Descriptions duplicate with the aforementioned will be hereinafter omitted.

Referring to FIGS. 3 and 4J, a second package P200 may be mounted on the first package P100 of FIG. 4I and thus a semiconductor package 1 may be manufactured. The semiconductor package 1 may be referred to as a package-on-package device, or a combined package. The second package P200 may include a second substrate 700 (which may also be referred to as a third substrate in relation to substrates 100 and 200), a second semiconductor chip 800, and a second molding layer 900. In one embodiment, the second semiconductor chip 800 may be mounted on the second substrate 700 in a flip-chip manner. In another embodiment, differently from those shown in figures, the second semiconductor chip 800 may be electrically connected to the second substrate 700 by a bonding wire (not shown). The second molding layer 900 may cover the second semiconductor chip 800 on the second substrate 700. Interconnect terminals 600 may be provided on a bottom surface of the second substrate 700. The interconnect terminals 600 may be coupled to the upper pads 223 and therefore the second package P200 may be electrically connected to the first package P100. FIG. 4J shows that one package is mounted on the first package P100, but the present inventive concept is not limited thereto, or alternatively a plurality of packages may be stacked on the first package P100. The substrate 100 to which external package connection terminals 140 are attached may be referred to as a package-on-package device substrate, or a combined package substrate, since it serves as a substrate for both packages P100 and P200 included in the package-on-package device.

As can be seen in the various figures, the semiconductor package 1 includes: a first bottom package having a first bottom substrate (e.g., a first redistribution substrate), a second top substrate (e.g., a first interconnect substrate), and a first bottom semiconductor chip; and a second top package that shares the first bottom substrate, and also uses a third substrate mounted on and above the first package (e.g., a second redistribution substrate), and has a second top, semiconductor chip. The first redistribution substrate includes first conductive lines for connecting external connection terminals of the semiconductor package 1 to the first bottom semiconductor chip, and includes second conductive lines for connecting external connection terminals of the semiconductor package 1 to the second top semiconductor chip through the first interconnect substrate. The second redistribution substrate includes conductive lines for connecting the second top semicondcutor chip to the external connection terminals of the semiconductor package 1 through conductive paths (e.g., through substrate vias) in the first interconnect substrate and the second conductive lines of the first redistribution substrate.

A method for manufacturing a semiconductor package according to the disclosed embodiments may induce the molding member to flow toward outside the interconnect substrate by forming the recess region spatially connected to an end of the gap between the interconnect substrate and the semiconductor chip. Through this, it may be achievable to disperse the pressure applied to the carrier substrate and prevent resin bleeding from occurring between the semiconductor chip and the carrier substrate. In addition, the flow direction of the molding member may be abruptly changed when the molding member flows into the recess region and thus the flow of the molding member may create turbulence in the recess region. As a result, it may be possible to allow the molding member to have an increased filling rate in the recess region and the gap between the interconnect substrate and the semiconductor chip, and thereby the occurrence of void may be reduced or suppressed.

Although the present invention has been described in connection with the embodiments illustrated in the accompanying drawings, it is not limited thereto, it will be apparent to those skilled in the art that various substitution, modifications, and changes may be made thereto without departing from the scope and spirit of the inventive concept.

What is claimed is:

1. A semiconductor package, comprising:
a redistribution substrate;
an interconnect substrate on the redistribution substrate, the interconnect substrate including a hole penetrating therethrough and a recess region in a lower portion thereof;
a semiconductor chip on the redistribution substrate, the semiconductor chip being disposed in the hole of the interconnect substrate; and
a molding layer covering the semiconductor chip and the interconnect substrate,
wherein the recess region is connected to the hole, and
wherein the molding layer fills the recess region and a gap between the semiconductor chip and the interconnect substrate.

2. The semiconductor package of claim 1, wherein the recess region extends from the hole toward an edge side of the interconnect substrate.

3. The semiconductor package of claim 2, wherein the recess region has a depth in a vertical direction which decreases with approaching from the hole toward the edge side of the interconnect substrate.

4. The semiconductor package of claim 2, wherein the recess region has a ring shape surrounding the hole, in plan view.

5. The semiconductor package of claim 2, wherein the recess region is provided in plural, the plurality of recess regions being spaced apart from each other along an outer side of the hole.

6. The semiconductor package of claim 1, wherein
the redistribution substrate includes a top surface in contact with a bottom surface of the semiconductor chip and a bottom surface of the interconnect substrate, and
the bottom surface of the semiconductor chip is positioned at the same level as the bottom surface of the interconnect substrate.

7. The semiconductor package of claim 1, wherein a plurality of semiconductors chip are provided in the hole.

8. The semiconductor package of claim 1, wherein the redistribution substrate further comprises insulative patterns and conductive patterns between the insulative patterns,
wherein the conductive patterns are electrically connected to the semiconductor chip.

9. The semiconductor package of claim 1, wherein the interconnect substrate further comprises:
an upper pad provided on an upper portion of the interconnect substrate;
a lower pad provided in a lower portion of the interconnect substrate; and
a through via that penetrates inside the interconnect substrate and is electrically connected to the upper pad and the lower pad,
wherein the through via is electrically connected to the redistribution substrate.

10. The semiconductor package of claim 9, further comprising an upper package on the interconnect substrate and the semiconductor chip,
wherein the upper package is electrically connected to the redistribution substrate by the through via of the interconnect substrate.

11. A semiconductor package, comprising:
a first substrate including a base layer including an insulative material;
a hole in the first substrate, the hole defined by inner sidewalls of the first substrate;
a first semiconductor chip disposed in the hole; and
a second substrate on which the first substrate and the first semiconductor chip are directly mounted,
wherein the inner sidewalls of the first substrate include a recess at a bottom of the hole.

12. The semiconductor package of claim 11, wherein the first substrate is an interconnect substrate, and the second substrate is a redistribution substrate.

13. The semiconductor package of claim 12, further comprising:
first conductive patterns formed through the redistribution substrate to connect external connection terminals of the semiconductor package to the first semiconductor chip; and
second conductive patterns formed through the redistribution substrate to connect external connection terminals of the semiconductor package to a second semiconductor chip disposed above the first semiconductor chip.

14. The semiconductor package of claim 11, wherein as a result of the recess, a top portion of the base layer that forms the first substrate forms an overhang in the base layer over the second substrate.

15. The semiconductor package of claim 11, wherein as a result of the recess, at least part of the bottom surface of the first substrate does not contact a top surface of the second substrate on which the first substrate is directly mounted.

16. The semiconductor package of claim 11, wherein the first semiconductor chip disposed in the hole includes a top surface, a bottom surface, and outer sidewalls connecting the top surface and the bottom surface, and further comprising:
a space between the outer sidewalls of the first semiconductor chip and the inner sidewalls of the first substrate, the space including the recess and an additional length of horizontal space.

17. The semiconductor package of claim 16, wherein the space between the outer sidewalls of the first semiconductor chip and the inner sidewalls of the first substrate is filled with a molding material,
wherein the molding material is formed of a continuous material that fills the space and also covers a top surface of the first semiconductor chip.

18. The semiconductor package of claim 16, wherein the first substrate is an interconnection substrate, and the second substrate is a redistribution substrate, and further comprising:
a third substrate disposed on the first substrate and the first semiconductor chip; and
a second semiconductor chip disposed on the third substrate,
wherein the third substrate is a redistribution substrate, and conductive patterns in the second substrate and the third substrate electrically connect the second semiconductor chip to external connection terminals of the semiconductor package.

19. A semiconductor package, comprising:
an upper substrate including a base layer including an insulative material;
a hole in the upper substrate, the hole defined by inner sidewalls of the upper substrate;
a first semiconductor chip disposed in the hole; and
a lower substrate on which the upper substrate and the first semiconductor chip are directly mounted,
wherein a portion of the upper substrate horizontally protrudes beyond a portion of the upper substrate that contacts the lower substrate.

20. The semiconductor package of claim 19, wherein the first semiconductor chip includes a top surface, a bottom surface, and outer sidewalls connecting the top surface and the bottom surface, and further comprising:
molding material filling a space between the outer sidewalls of the first semiconductor chip and the inner sidewalls of the upper substrate, wherein:
the space includes a portion horizontally between the outer sidewalls of the first semiconductor chip and the inner sidewalls of the upper substrate, and includes a portion vertically between the upper substrate and the lower substrate.
